(19) United States
(12) Patent Application Publication
(10) Pub. No.: US 2022/0216353 A1
(43) Pub. Date: Jul. 7, 2022

(54) OPTICAL SENSOR INCLUDING INTEGRATED DIFFUSER

(71) Applicant: ams AG, Premstaetten (AT)

(72) Inventors: Harald ETSCHMAIER, Eindhoven (NL); Gerhard PEHARZ, Eindhoven (NL); Arnold UMALI, Eindhoven (NL); Martin FACCINELLI, Eindhoven (NL)

(21) Appl. No.: 17/601,835

(22) PCT Filed: Mar. 27, 2020
(86) PCT No.: PCT/EP2020/058823

§ 371 Date: Oct. 6, 2021

Related U.S. Application Data
(60) Provisional application No. 62/830,704, filed on Apr. 8, 2019.

(51) Int. Cl. H01L 31/0232; H01L 31/0203; G02B 5/02

(52) U.S. Cl. CPC H01L 31/02327; G02B 5/0268; H01L 31/0203

(57) ABSTRACT

An apparatus comprises an optical sensor package that includes an optical sensor die. The optical sensor package further includes a reflow-stable optical diffuser disposed over the optical sensor die. The optical diffuser is surrounded laterally by an epoxy molding compound.

### FIELD OF THE DISCLOSURE

This disclosure relates to optical sensors including an integrated diffuser.

### BACKGROUND

Diffusers are optical elements that can be used to cause light to spread more evenly across a surface, reducing or removing high intensity bright spots. A diffuser can help make bright or harsh light softer by spreading it across a wider area. In some cases, an optical diffuser is used to absorb light into an optical sensor, such as a spectrometer or ambient light sensor.

Optical sensor modules that include diffusers may be incorporated into various types of consumer or other electronics products. Manufacturing processes for such products, however, sometimes involve relatively high temperatures (e.g., 260° C.). For example, surface mount technologies (SMT) used to mount a sensor module on a flex printed circuit substrate typically require such high temperatures as part of a reflow process. The high temperatures used during these processes may adversely impact the mechanical stability or optical performance of the diffuser.

### SUMMARY

The present disclosure describes optical sensor packages that include an integrated reflow-stable optical diffuser, as well as methods for manufacturing the optical sensor packages.

For example, in one aspect, an apparatus comprises an optical sensor package that includes an optical sensor die. The optical sensor package further includes a reflow-stable optical diffuser disposed over the optical sensor die. The optical diffuser is surrounded laterally by an epoxy molding compound.

Some implementations include one or more of the following features. For example, in some instances, a glass substrate is attached to the optical sensor die such that the glass substrate is disposed between the optical sensor die and the optical diffuser. In some cases, an optical aperture defined by a metal mask is disposed on the glass substrate. The glass substrate also can serves as a carrier for one or more optical filters.

The optical diffuser can be composed, for example, of a hardened epoxy resin material or silcone. In other implementations, the optical diffuser is composed of a porous quartz glass. In some cases, the optical diffuser has an outer surface that is flush with an outer surface of the epoxy molding compound.

In some instances, the epoxy molding compound also laterally surrounds the glass substrate and the optical sensor die.

In another aspect, the disclosure describes a method that includes attaching a glass substrate to a light sensitive surface of an optical sensor die, and performing a film assisted transfer molding process to provide an epoxy molding compound that laterally surrounds the optical sensor die and the glass substrate. The epoxy molding compound also defines a cavity over the glass substrate. The method includes providing a liquid epoxy resin material in the cavity, and curing the liquid epoxy resin material to form a reflow-stable optical diffuser.

In some instances, providing a liquid epoxy resin material includes dispensing the epoxy resin material into the cavity. In other cases the liquid material can be a silicone. In some cases, the method further includes sputtering a metal mask on the glass substrate to define an optical aperture.

In yet a further aspect, the disclosure describes a method that includes attaching a glass substrate to a light sensitive surface of an optical sensor die, and placing a reflow-stable optical diffuser on the glass substrate. The method also includes performing a film assisted transfer molding process to provide an epoxy molding compound that laterally surrounds the optical sensor die, the glass substrate and the optical diffuser.

In some implementations, the optical diffuser is composed of a porous quartz glass. In some cases, the optical diffuser is placed on the glass substrate by pick-and-place equipment.

Various advantages, some of which are described below, can be obtained in some implementations.

Other aspects, features and advantages will be readily apparent from the following detailed description, the accompanying drawings, and the claims.

### BRIEF DESCRIPTION OF THE DRAWINGS

FIG. 1 illustrates a side view of an example of an optical sensor package that includes an integrated optical diffuser.

FIG. 2 is a perspective view of the optical sensor package

FIG. 3 is a flow chart of an example process for manufacturing an optical sensor package.

FIG. 4 is a flow chart of another example process for manufacturing an optical sensor package.

FIG. 5 illustrates an example of an apparatus that includes an optical sensor package.

### DETAILED DESCRIPTION

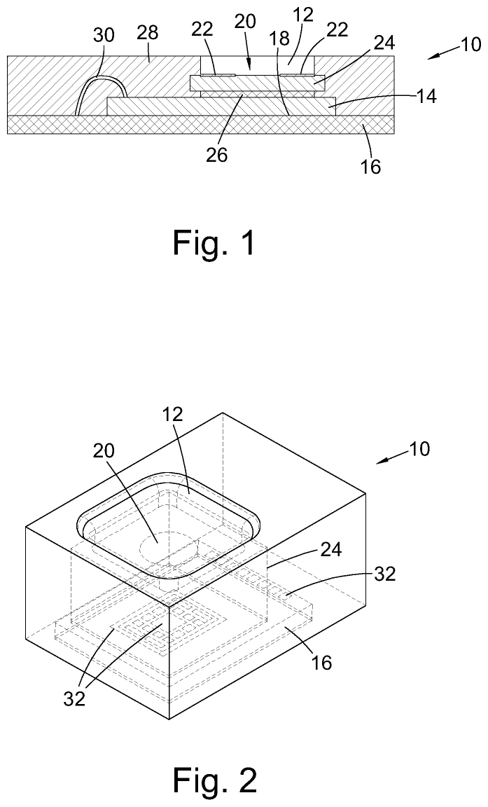

As shown in FIGS. 1 and 2, an optical sensor package 10 includes an integrated optical diffuser 12. As shown in the illustrated example of FIG. 1, an optical sensor die (e.g., semiconductor chip) 14 is mounted to a substrate 16 by a die attach film or other adhesive 18. Electrical connections such as contact pads on the backside of the sensor die 14, and wire bonds 30, can be provided to couple the sensor die to contact pads 32 on the substrate 16 (see FIG. 2, in which the sensor die 14 is omitted). The backside of the substrate 16 can include SMT or other contacts for mounting the package 10, for example, to a printed circuit board. For example, in some cases, the package 10 is a land grid array (LGA) package.

The package 10 has an optical aperture 20 defined, for example, by a metal mask 22 disposed on a glass substrate (e.g., a glass slide or cube) 24 that is attached to the sensor die 14. The glass substrate 24, which can be attached to the sensor die 14 by a die attach film or other adhesive 26, provides a fixed distance between the aperture 20 and the sensor die. The glass substrate 24 also can serve as a carrier for one or more optical filters. The diffuser 12 is disposed within a cavity defined in part by an epoxy molding compound (EMC) 28 that laterally surrounds the substrate 16, the sensor die 14 and the glass substrate 24.

The diffuser 12 preferably is composed of a reflow-stable material (i.e., a thermally stable material whose transmissivity remains substantially constant even when subjected to relatively high operating temperatures (e.g., 260° C.)). For example, in some implementations, the diffuser 12 is composed of silicone or an epoxy resin. As described below, such a diffuser can be formed, for example, by dispensing liquid silicone into the cavity defined by the EMC 28 and then curing (e.g., hardening) the silicone. In other implementations, the diffuser 12 is composed of porous quartz glass. As described below, such a diffuser can be provided, for example, in the form of a previously formed solid diffuser that is placed by pick-and-place equipment over the glass substrate 24. Preferably, the outer surface of the diffuser 12 is flush with the outer surface of the EMC 28.

As the diffuser is composed of a reflow-stable material, there is, in many instances, little if any drift of the sensor's optical parameters even after multiple reflow processes.

The size of the package 10 depends in part on the application. However, in general, the package 10 can be made ultra-compact. In a particular example, the package 10 has outer dimensions of about 2.5 mm×1.8 mm×1.5 m. Different dimensions may be appropriate for other implementations.

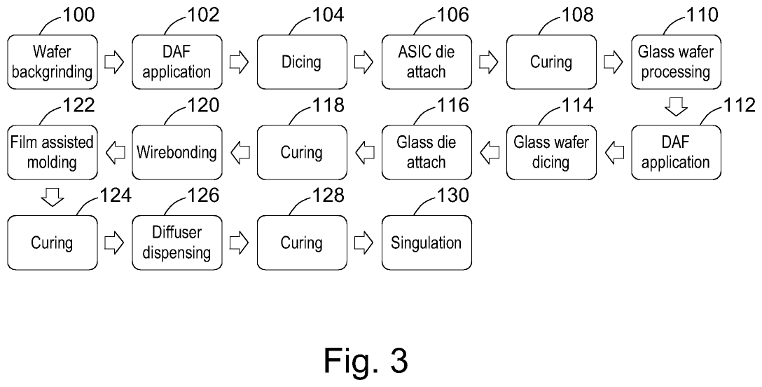

FIG. 3 shows an example process for manufacturing an optical sensor package 10 including an integrated optical diffuser 12. As indicated at 100, back grinding of a substrate (e.g., silicon) wafer is performed, followed by application of a first die attach film (DAF) or other adhesive (at 102). The substrate wafer then is diced into multiple individual integrated circuit dies (at 104), and one or more light receiver application specific integrated circuit (ASIC) dies are attached to a substrate array (at 106). The first DAF then is cured (at 108).

As indicated at 110, a glass wafer is processed, followed by application of a second DAF or other adhesive (at 112). Optical apertures can be defined on the glass wafer, for example, by photolithography and metal sputtering techniques. Such techniques can result in accurately positioned apertures that can be better aligned with the sensor dies. The glass wafer then is diced into multiple individual glass substrates (at 114). The glass substrates are attached, respectively, to the light-emitting surfaces of the ASIC dies (at 116), for example, using pick-and-place equipment, and the second DAF is cured (at 118). Wire bonds or other electrical connections can be formed for each sensor die (at 120).

In a subsequent step, as indicated by 122, a film assisted transfer molding (FAM) process is performed to provide an EMC, such as a black epoxy or other polymer material, which laterally surrounds the other components. In this process, the EMC defines a cavity over each glass substrate. In a subsequent step, as discussed below, a liquid diffuser material is provided in the cavity. In some instances, the FAM process includes application of a foil composed, for example, of poly-tetrafluoroethylene (PTFE), which serves as a non-adhesive layer and also provides protection of the transfer molding tool from the epoxy molding compound. The foil also allows the tool to touch and seal sensitive surfaces of the glass 24 without causing damage. The EMC then is cured (at 124).

Next, as indicated at 126, the liquid silicone or other material for the diffuser 12 is provided (e.g., by dispensing) in the cavity defined by the EMC. The liquid diffuser material then is cured (at 128). In some cases, a further singulation step may be performed by separating the substrate array into individual package units (at 130).

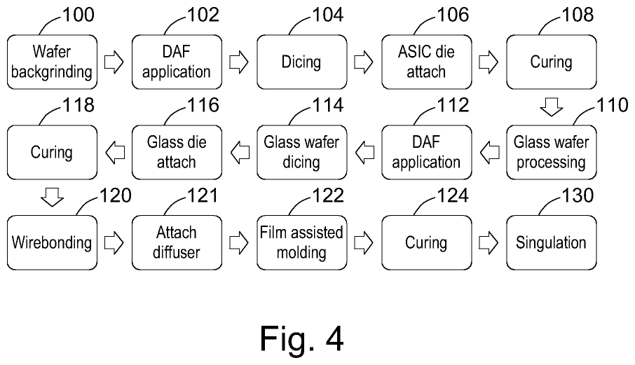

FIG. 4 illustrates an alternative process in which a previously-formed solid optical diffuser (e.g., porous quartz glass) is used instead of forming the diffuser by dispensing silicone into a cavity over the glass substrate. As shown in FIG. 4, most steps in the process are the same or similar to those described in connection with FIG. 3. However, after forming the wire bonds (at 120), a solid diffuser is attached to the glass substrate (at 121). Pick-and-place equipment can be used for this purpose. Subsequently, a FAM step is performed to provide an EMC, such as a black epoxy or other polymer material, which laterally surrounds the other components, including the optical diffuser (at 122). Thus, in the process of FIG. 4, the diffuser is attached to the glass substrate prior to performing the FAM step to form the EMC molded housing.

Various advantages can be obtained in some implementations. For example, by integrating a reflow-stable optical diffuser in the sensor module, calibration of the module can be performed at the unit level rather than at the system level. Thus, calibration can be performed, for example, prior to assembly of the sensor module into a host device such as a smartphone or other portable computing device. Further, using a reflow-stable diffuser can result in negligible drift of the sensor parameters even after reflow processes are performed (e.g., during assembly into a host device).

The processes described above also allow the glass substrates to be attached to the sensor die for each module individually rather than at the array level. This feature can facilitate alignment of the optical aperture with the sensor die. Further, the techniques allow the stack to be overmolded with an opaque epoxy molding compound, while the aperture is kept free of the molding compound during the FAM process.

The present techniques can be used with a range of optical sensors for various applications. Examples include ambient light sensors, infra-red spectrometers, and proximity sensors.

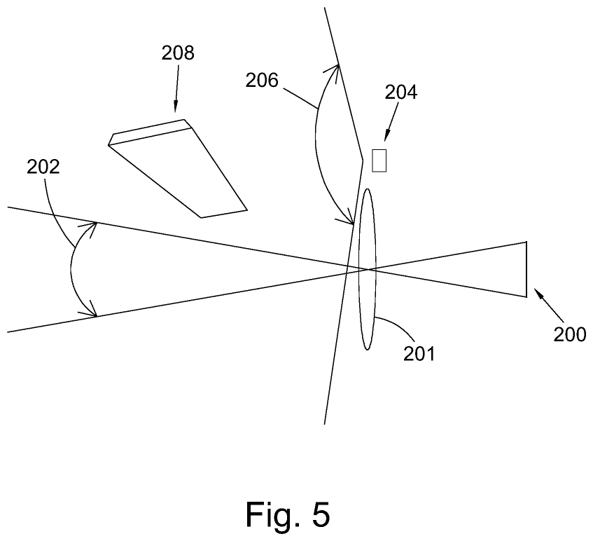

FIG. 5 illustrates a particular example in the context of a camera module that includes a camera sensor 200 and a lens 201 to give the camera sensor a field-of-view (FOV) 202. The camera module also includes an auxiliary ambient light sensor 204 that has a wide FOV 206. The ambient light sensor 204 can be implemented using an optical sensor package that includes an integrated optical diffuser as described above. The relatively wide FOV 206 of the ambient light sensor 204 can be used, for example, to detect light from a source 208 and classify the type of source (e.g., fluorescent, incandescent) based on the detected signals. Such information can be used, for example, to provide chromaticity coordinates and color temperature for improving white-color balancing. The camera module can be integrated, for example, into a smartphone, electronic notebook, computer tablet, or other portable computing device.

The design of smart phones and other computing devices referenced in this disclosure can include one or more processors, one or more memories (e.g. RAM), storage (e.g., a disk or flash memory), a user interface (which may include, e.g., a keypad, a TFT LCD or OLED display screen, touch or other gesture sensors, a camera or other optical sensor, a compass sensor, a 3D magnetometer, a3-axis accelerometer, a 3-axis gyroscope, one or more microphones, etc., together with software instructions for providing a graphical user interface), interconnections between these elements (e.g., buses), and an interface for communicating with other devices (which may be wireless, such as GSM, 3G, 4G, CDMA, WiFi, WiMax, Zigbee or Bluetooth, and/or wired, such as through an Ethernet local area network, a T-1 internet connection, etc.).

A number of implementations have been described. Nevertheless, various modifications may be made without departing from the spirit of the invention. For example, features described in connection with different embodiments may be combined into a single implementation. Accordingly, other implementations are within the scope of the claims.

1. An apparatus comprising:
an optical sensor package including an optical sensor die, the optical sensor package further including a reflow-stable optical diffuser disposed over the optical sensor die, the optical diffuser being surrounded laterally by an epoxy molding compound.

2. The apparatus of claim 1 further including:
a glass substrate attached to the optical sensor die, the glass substrate being disposed between the optical sensor die and the optical diffuser.

3. The apparatus of claim 2 further including an optical aperture defined by a metal mask disposed on the glass substrate.

4. The apparatus of claim 1 wherein the optical diffuser is composed of a hardened epoxy resin material.

5. The apparatus of claim 1 wherein the optical diffuser is composed of silicone.

6. The apparatus of claim 1 wherein the optical diffuser is composed of a porous quartz glass.

7. The apparatus of claim 1 wherein the optical diffuser has an outer surface that is flush with an outer surface of the epoxy molding compound.

8. The apparatus of claim 2 wherein the epoxy molding compound also laterally surrounds the glass substrate and the optical sensor die.

9. The apparatus of claim 2 wherein the epoxy molding compound defines a cavity on top of the glass substrate

10. The apparatus of claim 2 wherein the glass substrate is a carrier for one or more optical filters.

11. A method comprising:
attaching a glass substrate to a light sensitive surface of an optical sensor die;
performing a film assisted transfer molding process to provide an epoxy molding compound that laterally surrounds the optical sensor die and the glass substrate, wherein the epoxy molding compound defines a cavity over the glass substrate;
providing a liquid diffuser material in the cavity; and
curing the liquid diffuser material to form a reflow-stable optical diffuser.

12. The method of claim 11 wherein providing a liquid diffuser material includes dispensing an epoxy resin material into the cavity.

13. The method of claim 11 wherein providing a liquid diffuser material includes dispensing a silicone material into the cavity.

14. The method of claim 11 further including sputtering a metal mask on the glass substrate to define an optical aperture.

15. The method of claim 11 wherein the glass substrate serves as a carrier for one or more optical filters.

16. A method comprising:
attaching a glass substrate to a light sensitive surface of an optical sensor die;
placing a reflow-stable optical diffuser on the glass substrate; and
performing a film assisted transfer molding process to provide an epoxy molding compound that laterally surrounds the optical sensor die, the glass substrate and the optical diffuser.

17. The method of claim 16 wherein the optical diffuser is composed of a porous quartz glass.

18. The method of claim 16 wherein the optical diffuser is placed on the glass substrate by pick-and-place equipment.

19. The method of claim 16 further including sputtering a metal mask on the glass substrate to define an optical aperture.

20. The method of claim 16 wherein the glass substrate serves as a carrier for one or more optical filters.
